(19) United States
(12) Patent Application Publication
(10) Pub. No.: US 2014/0070168 A1
(43) Pub. Date: Mar. 13, 2014

(54) ELECTRONIC COMPONENT, METHODS FOR MANUFACTURING THE SAME AND USE OF GRAPHENE IN AN ELECTRONIC COMPONENT

(71) Applicants: Pierre Seneor, Paris (FR); Bruno Dlubak, Meudon (FR); Clement Barraud, Alfortville (FR); Sergio Tatay-Aguilar, Valencia (ES)

(72) Inventors: Pierre Seneor, Paris (FR); Bruno Dlubak, Meudon (FR); Clement Barraud, Alfortville (FR); Sergio Tatay-Aguilar, Valencia (ES)

(73) Assignees: UNIVERSITE PARIS-SUD, ORSAY (FR); THALES, NEUILLY SUR SEINE (FR)

(21) Appl. No.: 14/001,483

(22) PCT Filed: Feb. 24, 2012
(86) PCT No.: PCT/EP12/53127

§ 371 Date: Nov. 6, 2013

(30) Foreign Application Priority Data
Feb. 24, 2011 (FR) 1100553

(51) Int. Cl. H01L 29/16; H01L 21/02

(52) U.S. Cl. CPC H01L 29/1606; H01L 21/02527
USPC 257/26; 438/478

(57) ABSTRACT

The electronic component comprises at least two superposed conducting or semiconducting layers. According to one aspect of the invention, it comprises at least graphene layer interposed between the conducting or semiconducting layers, the conducting or semiconducting layers being electronically coupled through the thickness of said or each graphene layer. Application notably to tunnel junctions either magnetic or not, to spin valves, to memristors.

### CROSS-REFERENCE TO RELATED APPLICATIONS

This application is the National Stage under 37 U.S.C. §371 of International Application No. PCT/EP2012/053127, filed on Feb. 24, 2012, which claims priority to French Application No. 11 00553, filed on Feb. 24, 2011. The International Application published on Aug. 30, 2012 as WO 2012/113898. All of the above applications are incorporated herein by reference.

### FIELD OF THE INVENTION

The present invention relates to the field of electronic components, and in particular to an electronic component comprising at least two superposed conducting or semiconducting layers, either coupled electronically and/or magnetically.

### BACKGROUND

Electronic components include superposed layers including conducting, semiconducting and/or insulating layers which may have between them electronic and/or magnetic coupling. These different layers may be ferromagnetic, antiferromagnetic or amagnetic as well as organic or inorganic.

Such electronic components may for example define a tunnel junction, a magnetic tunnel junction, a spin valve, a memristor, a junction based on semiconductors, an abrupt conductor/semiconductor interface, an abrupt conductor/conduct interface between two magnetic and/or amagnetic conductors or an abrupt conductor/insulator interface.

When operating or during manufacture, such electronic components may reach high temperatures and/or are subject to high electric fields. This promotes migration of species between the layers of these electronic components. The result thereof is a loss of performances.

In order to avoid diffusion during steps for depositing layers or during annealing, it is possible to limit the temperature for depositing the layers or of the annealing.

In order to avoid diffusion during operation, it is possible to limit the temperature and/or the electric field during operation.

Nevertheless, these solutions are not satisfactory insofar that they are constraints in the design of electronic components and may limit the performances of the electronic component.

### SUMMARY

An object of the invention is to propose an electronic component wherein the phenomena of diffusion of species between two electronically coupled conducting or semiconducting layers are at least limited.

For this purpose, the invention proposes a component having at least two conducting or semiconducting layers coupled electronically and/or magnetically, at least one graphene layer interposed between the conducting or semiconducting layers, so that the conducting or semiconducting layers are electronically and/or magnetically coupled through the thickness of said or each graphene layer.

According to other examples, the electronic component includes one or more of the following features, taken individually or according to any of the technically possible combinations the two coupled layers are two conducting layers;
the two coupled conducting layers are amagnetic and have between them electronic coupling through the thickness of said or each graphene layer;
the two coupled conducting layers are ferromagnetic or antiferromagnetic and have between them electronic and/or magnetic coupling through the thickness of said or each graphene layer.
the two coupled layers have a conducting layer and a semiconducting layer;
the two coupled layers each have contact with a respective face of the graphene layer;
it further includes at least one intermediate layer interposed between the coupled layers;
said or each are intermediate layer is an electrically insulating or semiconducting layer;
it includes at least two intermediate layers;
it includes at least one graphene layer interposed between two intermediate layers;
a coupled layer and an intermediate layer are each in contact with a respective face of a graphene layer; and
said or each graphene layer is formed of a single graphene film.

The invention also relates to a method for manufacturing an electronic component having a first conducting or semiconducting layer and a second conducting or semiconducting layer electronically and/or magnetically coupled through the thickness of a graphene layer, having the steps of
providing the first layer,
depositing at least one graphene layer on the first layer, and
depositing the second layer over the graphene layer, so that said or each graphene layer separates the first layer and the second layer.

### BRIEF DESCRIPTION OF THE DRAWINGS

The invention further relates to the use of a graphene layer interposed between two conducting or semiconducting layers electronically and/or magnetically coupled of an electronic component for preventing diffusion of species between the conducting or semiconducting layers electronically and/or magnetically coupled through the thickness of the graphene layer.

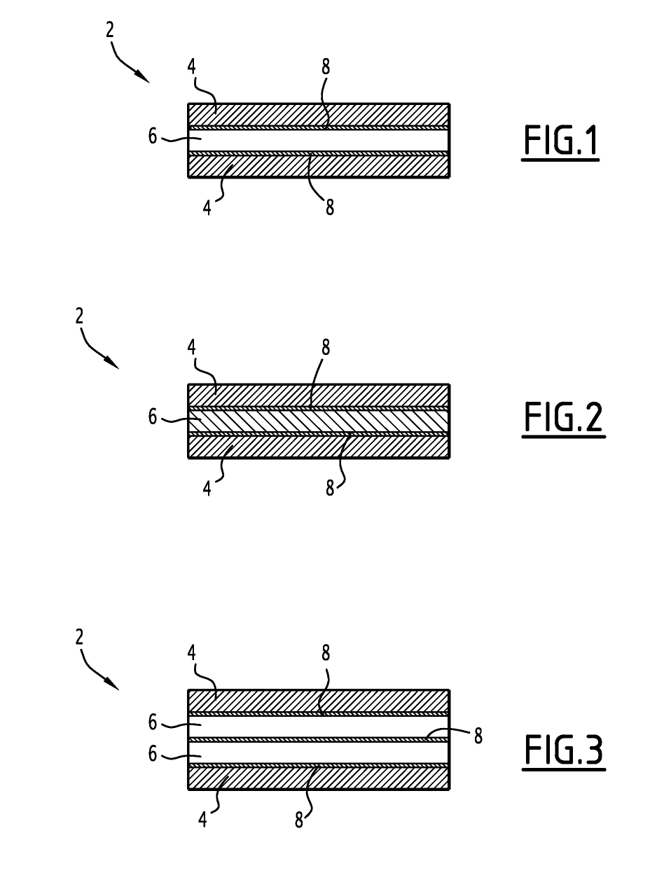

The invention and advantages thereof will be better understood upon reading the description which follows, only given as a non-limiting example, made with reference to the appended drawings wherein FIGS. 1 to 5 are schematic sectional views of electronic components according to different examples according to the invention.

### DETAILED DESCRIPTION

The electronic component 2 illustrated in FIG. 1 includes two metal electrodes 4 separated by at least one electrically insulating intermediate layer 6 interposed between both electrodes 4, here a single intermediate layer 6.

The electrodes 4 are formed by conducting layers positioned on either side of the intermediate layer 6. The electrodes 4 are electronically and/or magnetically coupled through the intermediate layer 6.

Two layers are electronically coupled when they are capable of exchanging electrons with each other. Electrons may directly pass from one layer to the other.

Two layers are magnetically coupled when at least one of the layers exerts a magnetic influence on the other.

The two electrodes 4 consist of the same material or of different materials.

The layers forming the electronic component 2 are parallel with each other and stacked along a stacking direction E perpendicular to the layers.

The electronic component 2 defines a simple non-magnetic conductor/insulator/conductor tunnel junction when the coupling between the electrodes is simply electronic or a magnetic conductor/insulator/conductor tunnel junction when the electrodes 4 are ferromagnetic and the coupling is electronic and magnetic.

The electronic component 2 further includes at least one graphene layer 8 interposed between each electrode 4 and the intermediate layer 6 and separating the electrode 4 from the intermediate layer 6.

The graphene layer 8 is formed with one or several superposed graphene films.

Graphene is a single-plane two-dimensional carbon crystal. A graphene film has a single-atom thickness. Such a film is extremely thin while forming an efficient diffusion barrier against the passage of molecules, atoms and ions. A graphene layer therefore defines an anti-diffusion barrier.

The graphene layer 8 interposed between each electrode 4 and the intermediate layer 6 defines a very effective barrier against the diffusion of species between the materials of the electrode 4 and of the intermediate layer 6, while allowing electronic and/or magnetic coupling between the electrodes 4 through the thickness of each graphene layer 8, because of the very great fineness of the graphene layer.

The electronic component 2 of FIG. 1 includes a graphene layer 8 interposed between each electrode 4 and the insulator 6.

In an alternative, the electronic component 2 includes a graphene layer between one of the electrodes and the intermediate layer, the other electrode being in contact with the intermediate layer.

The electronic component 2 of FIG. 2 differs from that of FIG. 1 in that the electrically insulating intermediate layer is replaced with a conducting or semiconducting intermediate layer 6.

The electronic component 2 defines a conductor/conductor/conductor junction or a conductor/semiconductor/conductor junction.

In an example, the electrodes 4 are magnetic, and the electronic component 2 of FIG. 2 defines a spin valve or a magnetic tunnel junction.

In another example, the electronic component 2 defines a light-emitting diode in particular and organic light-emitting diode or OLED. In this case, the intermediate layer 6 is a light-emitting organic semiconductor layer and the metal electrodes 4 may be magnetic or amagnetic.

An amagnetic electrode is for example made in an amagnetic conductor or an amagnetic conductor alloy. An amagnetic electrode is for example made in aluminium (Al), gold (Au), copper (Cu), silver (Ag), mercury (Hg), lithium (Li), platinum (Pt), indium tin oxide (ITO) or in an alloy thereof or in graphene/graphite.

A ferromagnetic electrode is for example made in a ferromagnetic metal, such as cobalt (Co), nickel (Ni), iron (Fe) or in an alloy of ferromagnetic metals, cobalt-iron-boron (CoFeB), nickel-iron (NiFe), or in a metal oxide such as manganites ((La, Sr)MnO₃) or in Heusler alloys such as Co₂MnSi, Co₂MnGe or Co₂FeAl₍₁₋ₓ₎Si₍ₓ₎.

A conducting intermediate layer 6 is made for example in metal or in a metal alloy such as gold (Au), copper (Cu), ruthenium (Ru) and silver (Ag).

An insulating or semiconducting intermediate layer 6 is organic or inorganic. A component may include several organic and/or inorganic intermediate layers 6.

An organic insulating or semiconducting intermediate layer 6 is for example formed with tris(8-hydroxyquinoline)aluminium(III) (Alq3), anthracene, polymers such as poly(para-phenylene-vinylene) (PPV) or polyfluorene (PFO) and/or self-assembled monolayers such as alkane-thiols or any other organic material or combination thereof.

The electronic component 2 of FIG. 3 differs from as that of FIG. 1 in that it includes two electrically insulating intermediate layers 6 interposed between the metal electrodes 4.

The intermediate layers 6 are separated by a graphene layer 8 interposed between the intermediate layers 6.

The electronic component 2 thus includes a graphene layer 8 between each electrode 4 and the intermediate layer 6 adjacent to this electrode 4, and a graphene layer 8 between the intermediate layers 6.

Alternatively, the electronic component 2 only includes a graphene layer 8 interposed between one of the electrodes 4 and the adjacent intermediate layer 6 or between the intermediate layers 6.

In another alternative, the electronic component 2 includes two graphene layers 8 each interposed between a respective electrode 4 and the adjacent intermediate layer 6, or interposed between an electrode 4 and the adjacent intermediate layer 6 and between the intermediate layers 6.

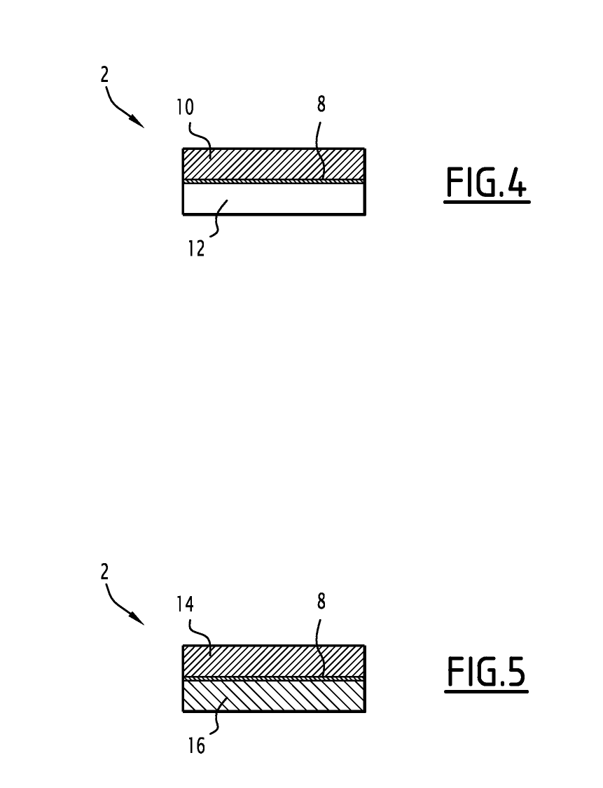

The electronic component 2 of FIG. 4 includes a stack of a conducting layer 10 and a semiconducting layer 12 separated by a graphene layer 8 interposed between the conducting layer 10 and the semiconducting layer 12. The conducting layer 10 and the semiconducting layer 12 are each in contact with a respective face of the graphene layer 8 on either side of the latter.

The conducting layer 10 and the semiconducting layer 12 define between them an abrupt interface and are coupled electronically.

The electronic component 2 of FIG. 5 includes a stack of two superposed magnetic layers 14, 16 separated by a graphene layer 8 interposed between the conducting layers 14. The magnetic layers 14, 16 are each in contact with a respective face of the graphene layer 8 on either side of the latter.

The magnetic layers 14 and 16 define between them an abrupt interface and are coupled magnetically.

In an example, a hard magnetic layer 14 is made in a harder magnetic material than the other soft magnetic layer 16.

The hard magnetic layer 14 is for example made in iron (Fe), cobalt (Co) or nickel (Ni).

The soft magnetic layer 16 is for example made in a cobalt-iron-boron alloy (CoFeB).

In an example, a magnetic layer 14 is made in a ferromagnetic material and the other magnetic layer 16 is made in antiferromagnetic material.

The antiferromagnetic layer 16 is for example made in iridium-manganese (IrMn), in cobalt oxide (CoO) or in bismuth ferrite (BiFeO₃).

A method for manufacturing an electronic component having a first conducting or semiconducting layer and a second conducting or semiconducting layer electronically and/or magnetically coupled through the thickness of a graphene layer, includes the steps of
providing the first layer,
depositing at least one graphene layer on the first layer, and
depositing the second layer over the graphene layer so that said or each graphene layer separates the first layer and the second layer.

In an example, the method includes, before the step for depositing said or each graphene layer on the first layer, a step for depositing an intermediate layer on the first layer.

In an example, the method includes, before the step for depositing the second layer, a step for depositing an intermediate layer over said or each graphene layer, and optionally an additional step for depositing at least one additional graphene layer on the intermediate layer.

A graphene film with single-atom thickness may be formed in a known way. According to a first known method, a graphene film with single-atom thickness is directly deposited on an electrode by physical vapor deposition. This method is known as [symbol] chemical vapor deposition [symbol] . According to a second known method, a graphene film is obtained by exfoliation of a graphite crystal. In both cases, the film may then be transferred onto a layer of the electronic component.

In the described electronic components, at least one graphene layer is interposed between two electronically coupled conducting or semiconducting layers, which gives the possibility of preventing or at least limiting the diffusion of species between these layers. The conducting or semiconducting layers remain electronically coupled through the thickness of said or each graphene layer.

In the described examples, the graphene layers are formed with a single graphene film with a single-atom thickness. It is possible to interpose a graphene layer formed with several superposed graphene films.

The invention applies to electronic components in general and to junctions in particular. As a nonlimiting example, the invention allows formation of tunnel junctions, either magnetic or not, spin valves, memristors, . . . etc.

1. An electronic component comprising:
at least two superposed conducting or semiconducting layers and
graphene layer interposed between the conducting or semiconducting layers,
wherein the conducting or semiconducting layers are electronically coupled through a thickness of said graphene layer so that the coupled layers may exchange electrons with each other through said graphene layer.

2. The electronic component according to claim 1, wherein the at least two coupled layers are two conducting layers.

3. The electronic component according to claim 2, wherein the at least two coupled conducting layers are amagnetic.

4. The electronic component according to claim 2, wherein the at least two coupled conducting layers are ferromagnetic or antiferromagnetic.

5. The electronic component according to claim 1, wherein the two coupled conducting layers are a conducting layer and a semiconducting layer.

6. The electronic component according to claim 1, wherein the two coupled layers are each in contact with a respective face of the graphene layer.

7. The electronic component according to claim 1, further comprising at least one intermediate layer interposed between the coupled layers.

8. The electronic component according to claim 7, wherein said or each are intermediate layer is an electrically insulating or semiconducting layer.

9. The electronic component according to claim 7 comprising at least two intermediate layers.

10. The electronic component according to claim 9, comprising at least one graphene layer interposed between two intermediate layers.

11. The electronic component according to claim 7, wherein a coupled layer and an intermediate layer are each in contact with a respective face of a graphene layer.

12. The electronic component according to claim 1, wherein said graphene layer is formed of a single grapheme film.

13. The electronic component according to claim 1, wherein both couple layers are coupled magnetically.

14. The electronic component according to claim 1, defining a simple or magnetic tunnel junction, in particular a simple conductor/insulator/conductor tunnel junction, a magnetic conductor/insulator/conductor tunnel junction, or a conductor/conductor/conductor junction or a conductor/semiconductor/conductor junction or a spin valve or a light-emitting diode, in particular an organic light-emitting diode (OLED).

15. A method for manufacturing an electronic component comprising a first conducting or semiconducting layer and a second conducting or semiconducting layer electronically coupled through the thickness of a graphene layer, comprising the steps of:
providing the first layer,
depositing at least one graphene layer on the first layer, and
depositing of the second layer over the graphene layer, so that said or each graphene layer separates the first layer and the second layer.

16. The use of a graphene layer interposed between two electronically coupled conducting or semiconducting layers of an electronic component for preventing the diffusion of species between the conducting or semiconducting layers electronically coupled through the thickness of the graphene layer.
